(19) United States
(12) Patent Application Publication
(10) Pub. No.: US 2014/0287549 A1
(43) Pub. Date: Sep. 25, 2014

(54) Method and Pre-Product for Producing a Thermoelectric Module

(71) Applicant: Robert Bosch GmbH, Stuttgart (DE)

(72) Inventors: Martin Koehne, Asperg (DE); Franz Wetzl, Mundelsheim (DE); Boris Kozinsky, Waban, MA (US)

(73) Assignee: Robert Bosch GmbH, Stuttgart (DE)

(21) Appl. No.: 14/215,583

(22) Filed: Mar. 17, 2014

(30) Foreign Application Priority Data
Mar. 19, 2013 (DE) 10 2013 204 813.0

(51) Int. Cl. H01L 35/34

(52) U.S. Cl. CPC H01L 35/34
USPC 438/54; 428/43

(57) ABSTRACT

A method for producing a thermoelectric module with a plurality of thermoelectric leg elements, which are electrically connected in series at opposite ends, includes arranging the leg elements on an electrically conducting plate, connecting the leg elements to the electrically conducting plate, and cutting up the electrically conducting plate into a plurality of conductor tracks, which respectively connect two of the leg elements to one another. From a further aspect, a pre-product for the production of a thermoelectric module by such a method includes an electrically conducting plate with a plurality of conductor track regions for the formation of conductor tracks. The electrically conducting plate has a lower mechanical stability in at least one zone of weakness between two conductor track regions than in the conductor track regions.

### CLAIM OF PRIORITY

This application claims priority under 35 U.S.C. §119 to patent application no. DE 10 2013 204 813.0, filed on Mar. 19, 2013 in Germany, the disclosure of which is incorporated herein by reference in its entirety.

### BACKGROUND

The present invention relates to a method for producing a thermoelectric module and to a pre-product for use in such a method.

Thermoelectric modules—integrated in a thermoelectric generator—allow power generation by using a temperature gradient in a system. FIG. 1 shows a classic type of thermoelectric module 100, which is integrated in a system with a hot side 160 and a cold side 162. The module 100 is enclosed by two thermally conductive, electrically insulating plates 134, 135. It comprises an alternating series connection of thermoelectric leg elements of the p type (conduction mechanism through defect electrons) 102 and the n type (conduction mechanism through electrons) 103, which are alternately electrically connected to one another by way of conductor tracks 125 on the hot side 160 and conductor tracks 124 on the cold side 162 in such a way as to obtain a series connection, both end points of which are led to the outside at two terminal conductor tracks 123.

FIG. 2 shows a schematically simplified front view of a pair of thermoelectric leg elements 102, 103 of the thermoelectric module 100 taken from FIG. 1, which are mechanically and electrically connected to one another in series at their upper ends 105 by way of an upper conductor track 125. At their lower ends 104, the leg elements 102, 103 are each connected to a further, lower conductor track 124, which continues the series connection in the direction of adjacent further leg elements (not shown) or serves as a terminal conductor track. A material-bonded connection 200 is respectively formed between the conductor tracks 124, 125 and the leg elements 102, 103. If the leg elements 102, 103 of thermoelectric material are kept at a high temperature at one end 105 and at a low temperature at the opposite end 104, an electric voltage with a sign that is dependent on the type of conduction is produced by the temperature gradient between the ends 104, 105 at each leg element 102, 103, caused by the thermal diffusion of electrons or defect electrons in the direction of the temperature gradient. On account of the series connection, the voltages of the individual leg elements 102, 103 are added together. If the end contacts of the series connection, for example in FIG. 2 the two lower conductor tracks 124, are electrically connected to one another, an electric current 202 flows, which allows the temperature gradient to be rendered usable directly as electric power.

In generator operation of the thermoelectric module from FIG. 1, a flow of heat 150 entering the module 100 from the hot side 160, which in FIG. 1 lies on top without this restricting generality, is conducted in through the upper electrically insulating plate 135 and the upper conductor tracks 125 into the upper ends 105 of the thermoelectric leg elements 102, 103, and at the same time a flow of heat 152, reduced by an electric power output 154 given off at the terminal conductor tracks 123, is conducted out from the lower ends 104 of the leg elements 102, 103 through the lower conductor tracks 124 and the lower electrically insulating plate 134. A thermoelectric module 100 of the type represented in FIG. 1 also allows an operating mode in reverse, for example in a cooling or heating device, in which the terminal conductor tracks 123 are connected to an external voltage source and an electric current is applied to them in order to bring about a desired temperature gradient.

On account of the large number of components in a thermoelectric module of the type explained on the basis of FIGS. 1 and 2, low-cost production of the module is a great challenge. The number of conductor tracks in a module corresponds approximately to the number of leg elements, so that, for example, in a module with 200 leg elements, almost 200 conductor tracks have to be set. Apart from the placing of the leg elements, this process also comprises the laborious placing of the individual conductor tracks onto the contact areas of the leg elements. The conductor tracks must be placed with high precision, since an offset of the conductor tracks may lead to disturbances due to short-circuits, insufficient contacting and the like in the module. In addition, before the placing, the conductor tracks and/or the contact areas of the leg elements must be coated with connecting material for the material-bonded connection. There is consequently a need for ensuring in a simple and reliable way precise placement of leg elements and conductor tracks in the production of thermoelectric modules.

### SUMMARY

Accordingly, a method is provided for producing a thermoelectric module with a plurality of thermoelectric leg elements, which have respectively opposite ends and are electrically connected in series by way of these ends. As long as they have opposite ends, the leg elements may in principle be of any geometrical form. The method comprises a step of arranging the leg elements on an electrically conducting plate, a step of connecting the leg elements to the electrically conducting plate and a step of cutting up the electrically conducting plate into a plurality of conductor tracks, which respectively connect two of the leg elements to one another. Since the leg elements are connected to the electrical plate and the electrically conducting plate is converted into the plurality of conductor tracks by the cutting up, the cutting up is performed after the connecting of the leg elements to the electrically conducting plate. Here, the expression “on” merely means the arranging of the leg elements on a face side of the electrically conducting plate, but without implying any particular alignment of the plate with respect to gravitational force. The term “electrically conducting plate” may also mean a structured, for example multilayered, plate with an electrically conducting layer, as long as an electrical connection between the leg elements and the electrically conducting layer is brought about by the connecting of the leg elements to the plate.

The fact that the conductor tracks are formed by the cutting up of the electrically conducting plate at a time at which the thermoelectric leg elements are already connected to the plate means that the production method according to the disclosure manages entirely without a step of separately placing the conductor tracks with respect to leg elements. On account of the large number of conductor tracks in typical thermoelectric modules, this reduces the number of required placement operations considerably, so that the production of the module can be performed with little effort in a short time. Since the conductor tracks form a series connection of the leg elements, even after the cutting up of the plate the thermoelectric module is mechanically held together, which makes it possible for a minimum spacing of the conductor tracks, which can be easily predetermined for example by the cutting width, to be maintained with such precision that the occurrence of short-circuits within the module, for example under mechanical flexion, is prevented with great certainty. As a result, very small tolerances can be realized in the dimensions of the gaps between the conductor tracks, without risking a short-circuit. A further advantage is that the original accuracy of the arrangement of the thermoelectric leg elements also leads in a simple and reliable way to an exact arrangement of the leg elements in the finished module, since the arrangement is fixed at an early stage by the connecting to the electrically conducting plate, and can no longer be influenced for example by vibrations during the cutting up of the electrically conducting plate.

According to a preferred development of the disclosed production method, a step of forming a slot in the region of at least one conductor track before the cutting up of the electrically conducting plate is additionally provided. The term slot may in this case refer both to an indentation or an incision in the direction of the thickness of the conductor track and to an incision in a direction running parallel to the surface of the conductor track. This measure makes it possible to influence the mechanical properties of the conductor track as required, without having to perform any laborious working of the conductor tracks, possibly putting at risk the mechanical stability of the module, when a connection to the leg elements already exists. For example, a mechanical stiffening of the module can be achieved by longitudinal slots in the direction of the thickness in particular, or a mechanical flexibilizing of the module can be achieved by transverse slots in the direction of the thickness or the direction of a surface. The latter also makes it possible, in a way similar to the formation of a zone of weakness between conductor track regions, that the conductor track regions can already adapt themselves to dimensional deviations of the leg elements within existing tolerance limits before the connecting to the leg elements, so that a particularly secure connection between the conductor track regions and the leg elements can be formed in a gentle way, with only little pressing pressure.

According to a preferred development, the arranging of the leg elements is performed in rows. In this case, the production method also has a step of inserting at least one row spacer in at least one row interspace between adjacent rows of the leg elements. This makes it possible to ensure a spacing of the rows of leg elements that is predetermined by the spacer, in particular until the position of the leg elements is fixed by the connecting to the electrically conducting plate. The inserting of the at least one row spacer is preferably performed before the arranging of the leg elements, which facilitates the arranging operation and avoids already arranged leg elements being bumped during the insertion. Moreover, the inserting is preferably performed into the lower part of a clamping device, which advantageously makes subsequent stabilization by means of the clamping device possible without putting the arrangement at risk by transporting it.

The arranging of the leg elements is preferably also performed in columns, which run at an angle in relation to the rows, for example at a right angle in relation to them, the production method having a further step of inserting at least one column spacer into at least one column interspace between adjacent columns of the leg elements. This makes it possible to ensure a spacing also of the columns of the leg elements that is predetermined by the spacer, and consequently completely establish the position of the leg elements in the plane of the plate with great accuracy and reliability, in particular until the position of the leg elements is fixed by the connecting to the electrically conducting plate. In the sense of a further meaning, the term “rows” can also be applied to the columns, and similarly the terms “row interspace”, “row spacer”, etc. can be applied to the corresponding terms that relate to columns

According to a preferred development, the connecting of the leg elements to the electrically conducting plate is performed by forming a material-bonded connection between the leg elements and the electrically conducting plate. This makes a mechanically stable connection with low electrical connection resistance possible. For this purpose, the production method preferably comprises a step of applying a connecting material for the material-bonded connection to the electrically conducting plate and/or the leg elements. This makes it possible by the use of a third material, which can be optimized with regard to the desired mechanical and/or electrical connection properties, to achieve a particularly high quality of mechanical and/or electrical connection. The forming of the material- bonded connection is preferably performed by a heat treatment for melting and/or sintering the connecting material. In this way, the connecting step can be externally controlled precisely, without mechanical access to the location of the connection being required.

According to a preferred development, the cutting up of the electrically conducting plate is performed by means of a laser beam, an electron beam, a high-pressure water jet or a cut-off wheel. In this way, the conductor tracks can be formed gently, without great mechanical forces putting at risk the bonded assembly of the leg elements and the electrically conducting plate or the conductor tracks produced from it.

According to a preferred development, the production method also comprises a step of arranging a further electrically conducting plate on the leg elements, opposite from the electrically conducting plate, i.e. on the side of the leg elements that is facing away from this plate. Additionally provided are a step of connecting the leg elements to the further electrically conducting plate and a step of cutting up the further electrically conducting plate into a further plurality of conductor tracks, which respectively connect two of the leg elements to one another, after the connecting of the leg elements to the electrically conducting plate and the connecting of the leg elements to the further electrically conducting plate. This makes it possible in a simple way to place the conductor tracks on both sides of the thermoelectric module with high precision.

According to a preferred development, the production method also comprises a step of filling a powdered substance in between the electrically conducting plate and the further electrically conducting plate, before the cutting up of the electrically conducting plate and/or the cutting up of the further electrically conducting plate. This makes it possible to limit the cutting action of the tool used for the cutting up to the electrically conducting plate or the further electrically conducting plate that is to be cut up, in order in this way to avoid damage to the opposite further electrically conducting plate or the electrically conducting plate, the leg elements or a spacer possibly placed between the leg elements.

From a further aspect, the disclosure provides a pre-product for the production of a thermoelectric module by such a method. The pre-product comprises an electrically conducting plate with a plurality of conductor track regions for the formation of conductor tracks, the electrically conducting plate having as a result of an appropriate, for example mechanical or chemical, pretreatment a lower mechanical stability in a zone in the bordering region between a region of one conductor track and a further region of the electrically conducting plate than in the conductor track regions. This zone is referred to hereinafter as a zone of weakness. By being used in the above method as the electrically conducting plate, such a pre- product makes particularly rapid production of the thermoelectric module possible, since, on account of the already existing zone of weakness, the step of cutting up the plate in the region of the zone of weakness requires less cutting effort. Moreover, the pre-product makes a limited mobility of the conductor track regions with respect to one another possible along the zone of weakness, for example by slight flexion, so that the conductor track regions can already adapt themselves to dimensional deviations of the leg elements within existing tolerance limits before the connecting to the leg elements, which means it is possible to form a particularly secure connection between the conductor track regions and the leg elements in a gentle way, with only little pressing pressure.

According to a preferred development of the pre-product according to the disclosure, the zone of weakness has at least one clearance in the electrically conducting plate and/or a smaller thickness of the electrically conducting plate in relation to the conductor track regions. For example, the zone of weakness may be perforated by a multiplicity of small clearances, or the zone of weakness may be formed by large clearances that are only interrupted by thin webs.

According to a preferred development, at least one slot is formed within at least one conductor track region. For example, in one or more conductor track regions a number of slots form a meandering contour, so that the production of a flexible thermoelectric module in a simple way is made possible.

### BRIEF DESCRIPTION OF THE DRAWINGS

FIG. 1 is a cut-away perspective view of a thermoelectric module given by way of example;

FIG. 2 is a schematic representation of a pair of thermoelectric leg elements of a thermoelectric module, which are connected in series by way of conductor tracks;

FIGS. 3A-B are plan views of an upper and a lower electrically conducting plate, which are provided in a method according to one embodiment of the disclosure for producing a thermoelectric module;

FIGS. 4A-B are plan views of the upper and lower electrically conducting plate from FIG. 3, after connecting material has been applied in a further step of the production method;

FIGS. 5A-F are front views of a clamping device during use in method steps of a production method according to one embodiment;

FIG. 6 is a plan view of an electrically conducting plate during the insertion of spacers in a production method according to one embodiment;

FIGS. 7A-B are sectional views of a thermoelectric module at the beginning and after completion of a step in a production method according to one embodiment in which electrically conducting plates are cut up;

FIGS. 8A-B are schematic plan views of respective conductor track planes which are obtained in a production method according to one embodiment by cutting up a lower and an upper electrically conducting plate;

FIG. 9 is a plan view of a pre-product according to one embodiment for the production of a thermoelectric module; and

FIG. 10 is a flow diagram of a method, according to one embodiment of the disclosure, for producing a thermoelectric module.

### DETAILED DESCRIPTION

Unless otherwise expressly mentioned, the same reference signs in the figures relate to the same or equivalent elements. Similarly, unless otherwise expressly mentioned, spatial designations such as “top”, “bottom”, “upper”, “lower”, “above”, “below”, “on”, “over”, “under”, etc. are not intended to specify any particular arrangement of elements with respect to the direction of gravitational force, but are only used for the purpose of an easily understandable description of the relative arrangement of various elements.

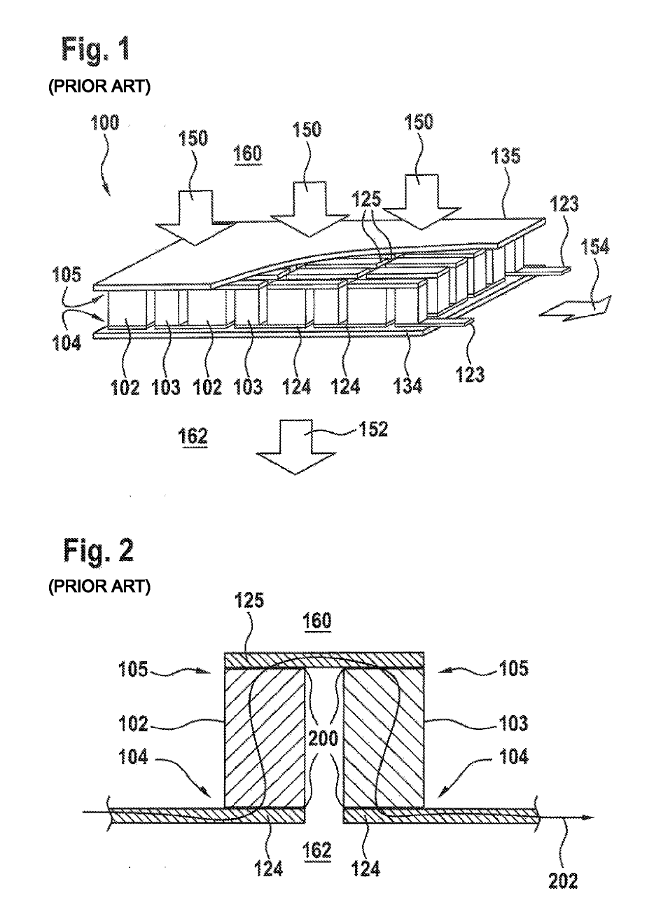

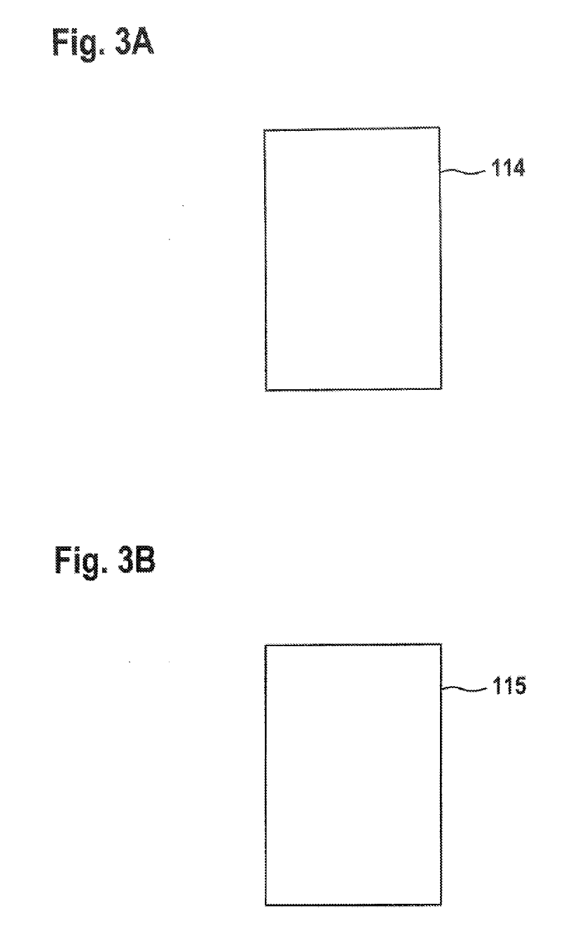

A production method according to one embodiment of the disclosure, by which a thermoelectric module of the basic type explained above on the basis of FIGS. 1 and 2 is produced, is to be described below with reference to FIGS. 3A to 8B.

According to the method, first a lower electrically conducting plate 114, shown in FIG. 3A, is provided, intended for being used in a later method step to form conductor tracks 124 that in FIG. 1 lie in a plane below the leg elements 102, 103. Similarly, an upper electrically conducting plate 115, shown in FIG. 3B, is provided, intended for being used in a later method step to produce the upper conductor tracks 125 that are represented in FIG. 1.

Both electrically conducting plates 114, 115 may be formed from the same material and have identical dimensions, which in the present embodiment coincide with the rectangular surface dimensions of the thermoelectric module to be produced. The material for the electrically conducting plates 114, 115 preferably has a coefficient of thermal expansion that deviates only slightly from that of the thermoelectric material in the leg elements of the thermoelectric module to be produced, and preferably has both a good electrical conductivity and a high thermal conductivity. Metals and metallic composite materials, such as for example nickel, cobalt, iron, niobium, titanium, zirconium, molybdenum, molybdenum-copper, molybdenum-nickel, magnesium-carbon fiber and copper-carbon fiber, are suitable in particular. Apart from solid materials, it is also possible for example to use multilayered materials with at least one electrically conducting layer for the provision of the electrically conducting plates 114, 115. The plates are cleaned and dried, so that there are no longer any impurities on the surface, and possibly present surface oxides are removed.

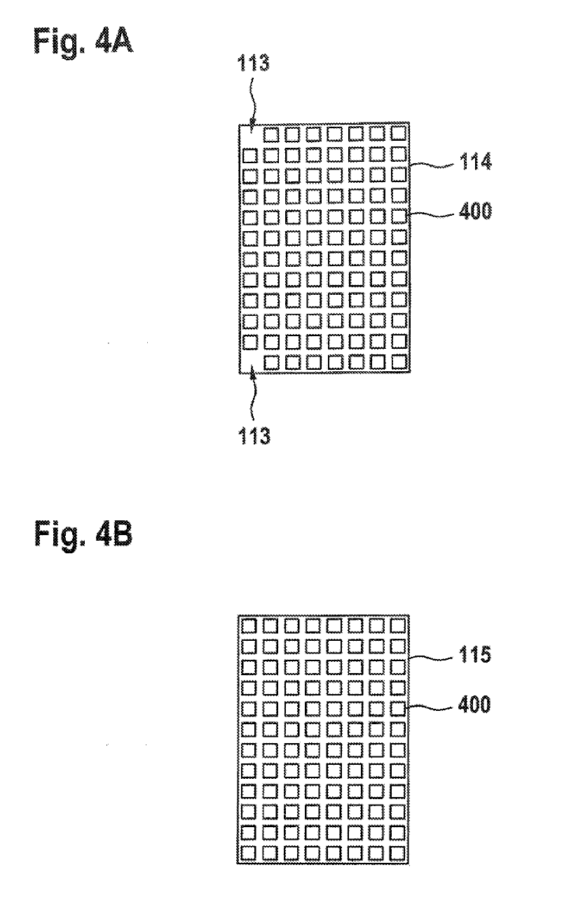

As shown in FIGS. 4A and 4B, the electrically conducting plates 114, 115 are subsequently coated with a connecting material 400 for the formation of a material-bonded connection. This connecting material 400 may for example take the form of a tin-containing foil, a paste of hard solder, soft solder or a silver- containing powder, and, for example in the case of a paste, be applied to respectively one side of the electrically conducting plates 114, 115 by screen printing, stencil printing or by a suitable spraying method, the connecting material being applied to the electrically conducting side if a layer material with only one electrically conducting side is used. In the present embodiment, the connecting material 400 is only applied at those locations at which thermoelectric legs are later to be arranged in a way corresponding to their intended position in the thermoelectric module to be produced. In the case of the lower electrically conducting plate, two free locations 113 are left without connecting material 400 in corners for the later attachment of terminal conductor tracks. In alternative embodiments, the electrically conducting plates 114, 115 may for example also be covered with the connecting material over the entire surface area, with or without leaving free locations for terminal conductor tracks.

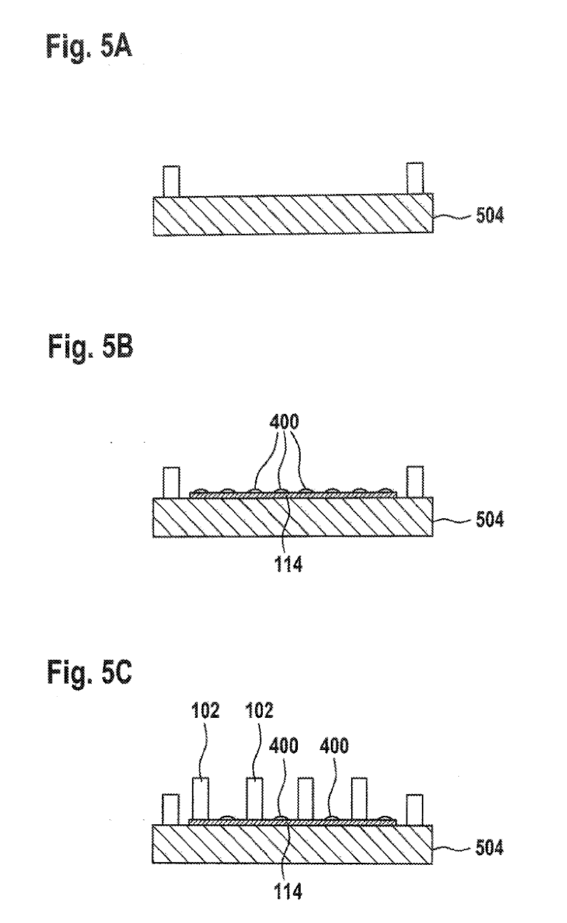

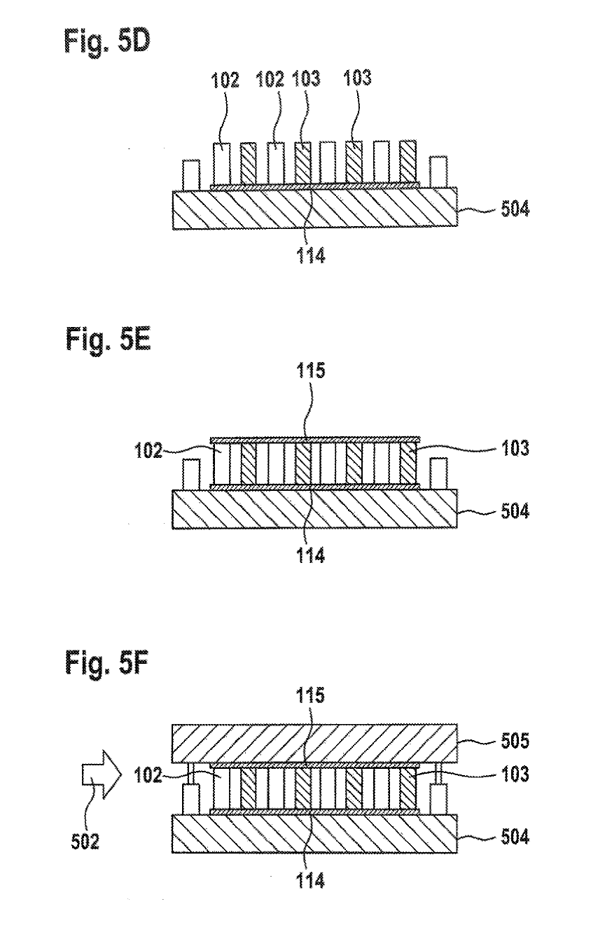

The next method steps are carried out in a two-part clamping device 504, 505, which is shown in front view in FIGS. 5A-F and has a lower part 504 and an upper part 505. First, as shown in FIG. 5A, the lower part 504 of the clamping device, which has surface dimensions at least corresponding to the surface area of the thermoelectric module to be produced, is provided in an open form. In a further method step, as shown in FIG. 5B, the lower electrically conducting plate 114 is placed into this lower part 504 in such a way that the side provided with the connecting material 400 faces upward, i.e. away from the lower part 504 of the clamping device 504, 505.

Subsequently, the lower electrically conducting plate 114 is first loaded with thermoelectric leg elements 102 of the p type, as represented in FIG. 5C. This involves placing a leg element 102 onto every second location provided with the connecting material 400, in a respectively alternating manner similar to a checkerboard. For the sake of a simple representation, FIG. 5C only shows one row of leg elements 102, lying in the plane of the drawing, while leg elements positioned further behind, in rows lying behind the plane of the drawing, have been omitted. In the remaining gaps, leg elements 103 of the n type are placed, as shown in FIG. 5D. In alternative embodiments, the setting of the leg elements 102, 103 may also be performed at the same time or in any other desired sequence. The leg elements 102, 103 consist of a suitable thermoelectric material of the corresponding type of conduction, for example skutterudite, a half-Heusler alloy, lead telluride, silicon or bismuth telluride, and have in the present embodiment the geometrical form of columns with a square base area, the side length of which is 2.4 mm.

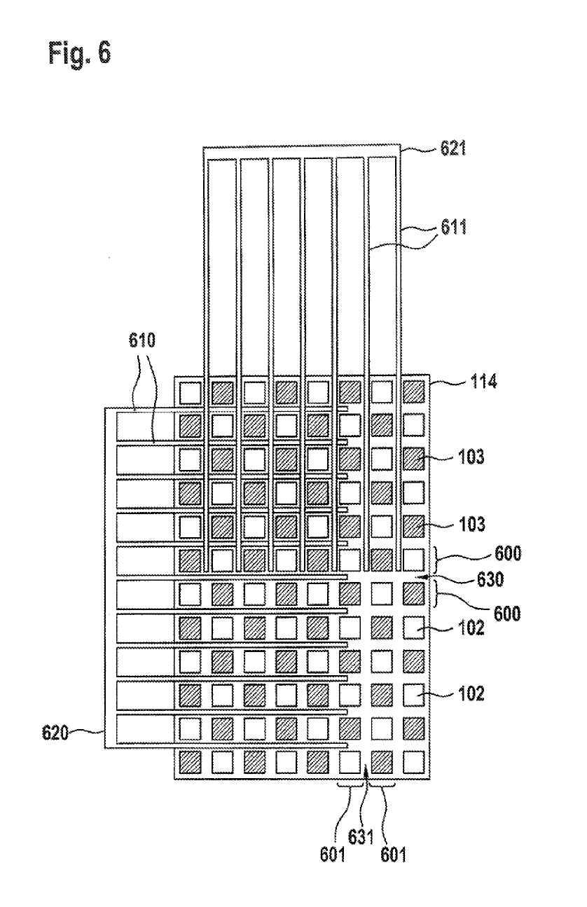

To facilitate the loading, two comb-like auxiliary tools (fixing combs) 620, 621, which have their prongs 610, 611 at an angle of 90° in relation to one another, may expediently be inserted, as shown in FIG. 6 in a schematic plan view of the lower electrically conducting plate 114 loaded with the leg elements 102, 103 in an alternating manner similar to a checkerboard. In this case, the prongs 610 of the first fixing comb 620 respectively form a row spacer, which ensures a spacing 630 between adjacent rows 600 of the leg elements 102, 103, and the prongs 611 of the second fixing comb 621 respectively form a column spacer, which ensures a spacing 631 between adjacent columns 601 of the leg elements 102, 103. The fixing combs 620, 621 have the effect of preventing the leg elements 102, 103 from being displaced or twisted. For the sake of overall clarity, the fixing combs 620, 621 are not represented in FIGS. 5A-F.

In a subsequent step, which is shown in FIG. 5E, the upper electrically conducting plate 115 is placed onto the leg elements 102, 103, its side that is provided with the connecting material facing downward, so that the connecting material comes into contact with the leg elements 102, 103. It can at the same time be ensured by a suitable auxiliary element that is not shown, such as for example a centering pin, that the upper electrically conducting plate 115 is positioned exactly over the lower electrically conducting plate 114 and there are not any differences or alignment errors between the two plates 114, 115.

As shown in FIG. 5F, the upper part 505 of the clamping device 504, 505 is placed onto the three-layered arrangement thus produced, comprising the lower electrically conducting plate 114, the leg elements 102, 103 and the upper electrically conducting plate 115, and is braced with the lower part 504. As a result, the three-layered arrangement 114, 102, 103, 115 is put under pressure, and slipping or twisting of the leg elements 102, 103 is no longer possible. The three-layered arrangement 114, 102, 103, 115 braced in the clamping device 104, 505 is put into an oven (not shown) for a heat treatment 502. After the heat treatment 502, the clamping device 504, 505 is opened and the three-layered material-bonded assembly produced, comprising the lower electrically conducting plate 114, the leg elements 102, 103 and the upper electrically conducting plate 115, is removed.

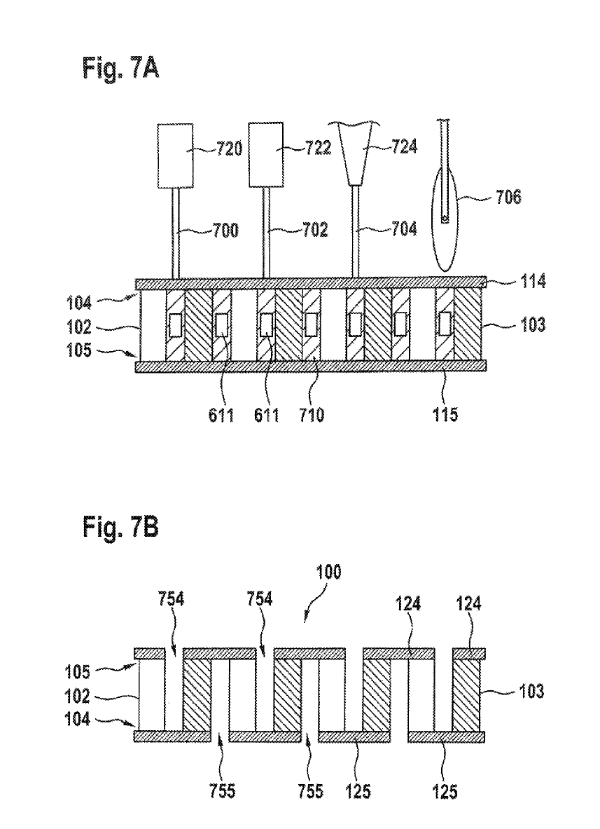

FIG. 7A shows in a schematic sectional view the three-layered material-bonded assembly produced, comprising the lower electrically conducting plate 114, the leg elements 102, 103 and the upper electrically conducting plate 115, after its removal from the clamping device. In a subsequent method step, the two electrically conducting plates 114, 115 are cut by means of a suitable cutting process in such a way as to produce from them the conductor tracks 124, 125. A laser beam 700 generated by means of a laser 720, an electron beam 702 generated by means of an electron beam source 722, a high-pressure water jet 704 directed from a nozzle 724 or a thin cut-off wheel 706 may be used for example as the cutting tool. It goes without saying that the selection of one of the aforementioned cutting means 700, 702, 704, 706, shown by way of example in FIG. 7A, is sufficient.

Before carrying out the cutting process, in particular if it is to be carried out with the aid of a laser beam 700 or an electron beam 702, the free space still remaining between the electrically conducting plates 114, 115 is filled with a protective substance 710, in order to prevent damage to the leg elements 102, 103, the regions of the respectively opposite conductor tracks 124, 125 or possibly used auxiliary tools, such as for example the prongs 611 of a fixing comb. An aluminum-oxide powder or a magnesium-oxide powder may be used for example as the protective substance 710. In the present embodiment, the cutting process itself is first carried out for the lower electrically conducting plate 114, which for this purpose is turned upward, facing the cutting means 700, 702, 704, 706 in FIG. 7A. After the cutting up of the lower electrically conducting plate 114 into the lower conductor tracks 124, the three-layered material-bonded assembly is turned over, so that the upper electrically conducting plate 115 faces in the direction of the cutting means 700, 702, 704, 706. After the cutting up of the upper electrically conducting plate 115 into the upper conductor tracks 125, auxiliary tools that are possibly used, such as fixing combs, and the protective substance 710 are removed from the interior of the thermoelectric module 100. This cleaning may be carried out for example by suction extraction, blowing out or flushing out.

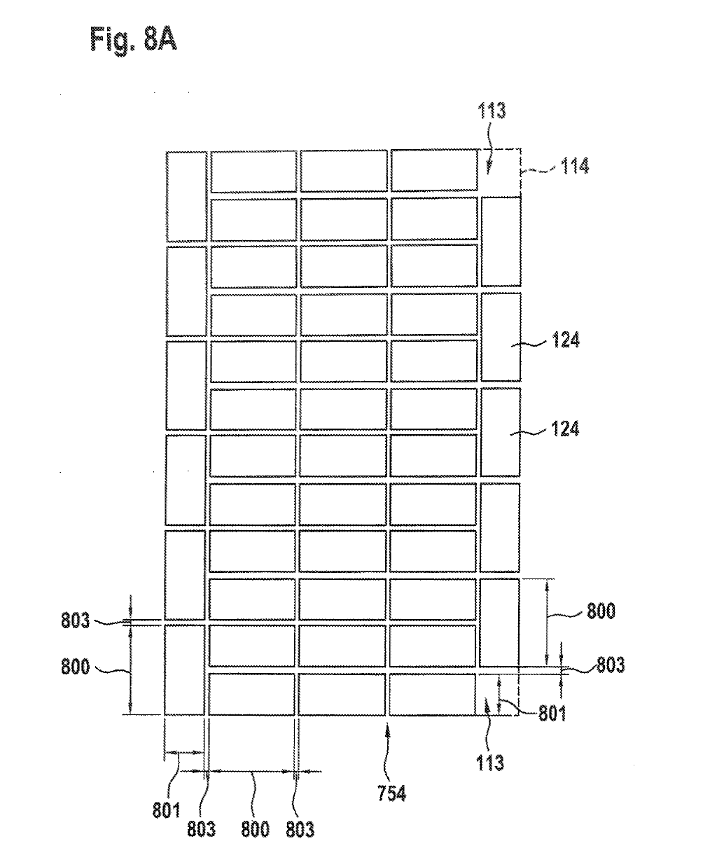

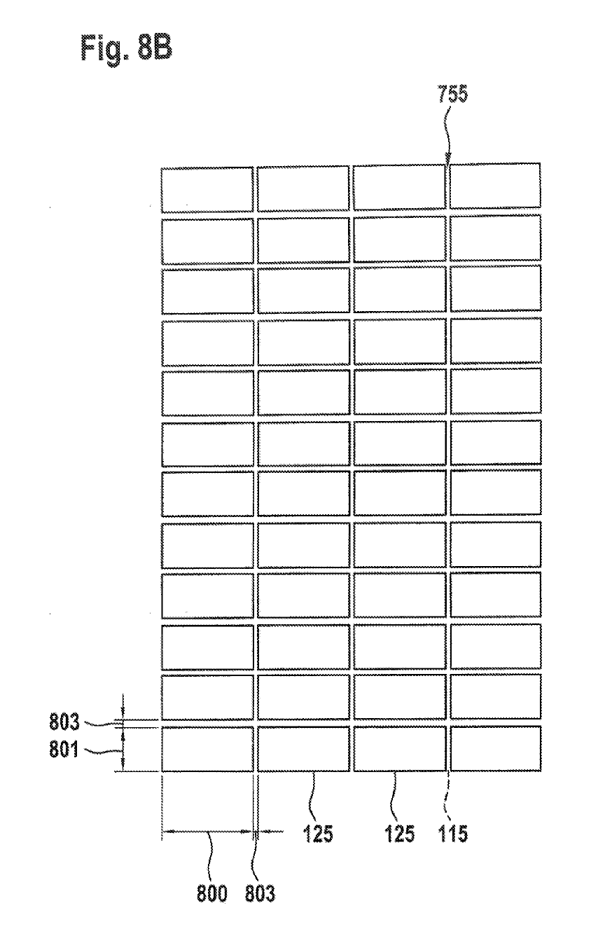

FIG. 8A shows a schematic plan view of the conductor tracks 124 that are formed by the cutting up of the lower electrically conducting plate 114 and together form a lower conductor track plane of the thermoelectric module. For the sake of overall clarity, further component parts of the thermoelectric module have not been represented. In the present embodiment, the conductor tracks 124 are formed from nickel sheet of a thickness of 1 mm and respectively have the form of a rectangle, in which the long side has a length 800 of 7.5 mm, and the short side has a length 801 of 3.5 mm. A gap 754 with a width 803 of 0.5 mm, produced by the cutting width, is respectively produced between the conductor tracks 124. At the free locations 113, where the lower electrically conducting plate 114 has not been provided with the connecting material, parts that are not required have been removed, in order in a subsequent step to attach the terminal conductor tracks for the external connection of the thermoelectric module to the lower ends of the leg elements located there (not shown in FIG. 8A) that are exposed under the free locations 113.

FIG. 8B correspondingly shows a schematic plan view of the conductor tracks 125 that are formed by the cutting up of the upper electrically conducting plate 115 and together form an upper conductor track plane of the thermoelectric module. For the sake of overall clarity, here too further component parts of the thermoelectric module have not been represented. The material and dimensions 801, 802 of the conductor tracks and also the width 803 of the cutting gap 755 formed by the cutting up of the upper electrically conducting plate are as in FIG. 8A.

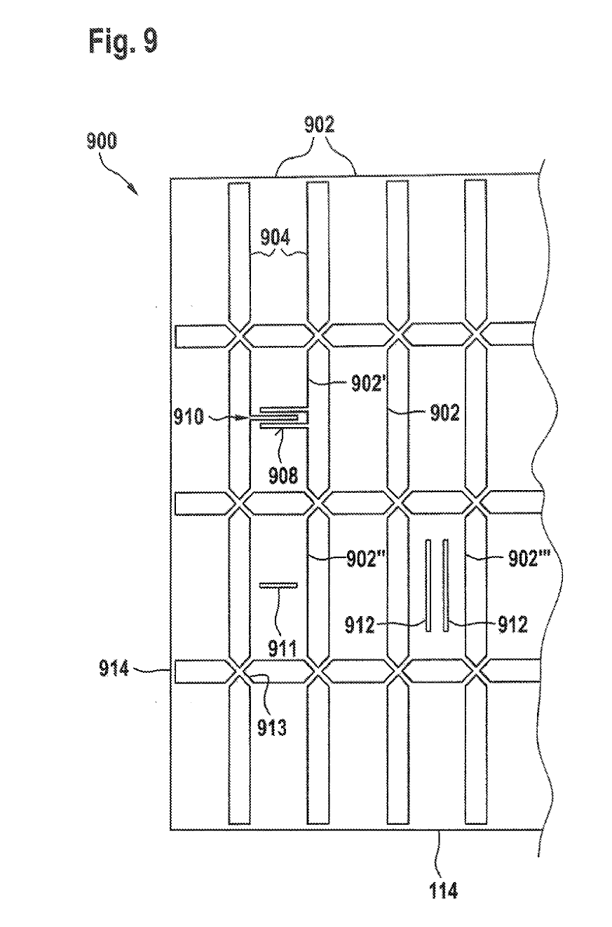

In the embodiment described above of the production method, solid plates of a simple rectangular form were used as the electrically conducting plates 114, 115. FIG. 9 shows an example of an electrically conducting plate 114, which according to a further embodiment has been pre-formed by punching and the like as a pre-product 900 for a production method. The electrically conducting plate 114 has zones of weakness 904, formed between conductor track regions 902. Zones of weakness are physically or chemically pretreated bordering regions between the conductor tracks respectively to be formed and the rest of the electrically conducting plate 114. In the present embodiment, the zones of weakness 904 each consist of a punched-out clearance, so that only thin webs 914, 913 remain between the conductor track regions, the webs 913 that are surrounded by four conductor track regions being configured in the form of a cross. As a result, both the time requirement for the later cutting up and also the required power of the cutting means, for example a laser, are reduced. A further advantage is that the flexibility of the plate 114 is increased, and as a result better adaptation to height tolerances of the leg elements is possible and the distortion of the plate 114 can be compensated with much less pressing force when connecting to the leg elements. In addition, a possible distortion of the plate 114 during a heat treatment when connecting is avoided as a result of the flexibility of the electrically conducting plate 114.

The pre-product 900 shown in FIG. 9 comprises further pre-structurings 908, 910, 912, illustrated by way of example, by which the properties of the thermoelectric module to be produced and the sequence of the production method can be influenced as required. Thus, in a first structured conductor track region 902′, a meandering structure 908 is formed by three slots 910 cut out in an alternating manner from both sides of the conductor track region 902′ in the lateral direction. The meandering structure 908 is arranged centrally in the conductor track region 902′, so that the conductor track formed in the finished module has an increased elasticity between the leg elements that are connected by it. In a second structured conductor track region 902″, a slot 911 is likewise centrally formed, is directed transversely in relation to the conductor track region 902″ and has a similarly flexibilizing effect. In a third structured conductor track region 902′″, two slots 912, directed parallel to the conductor track region 902′″, are formed, giving the conductor track region concerned a corrugated sheet-like structuring, which leads to a particular stiffness of the conductor track region 902′″, and consequently of the thermoelectric module as a whole.

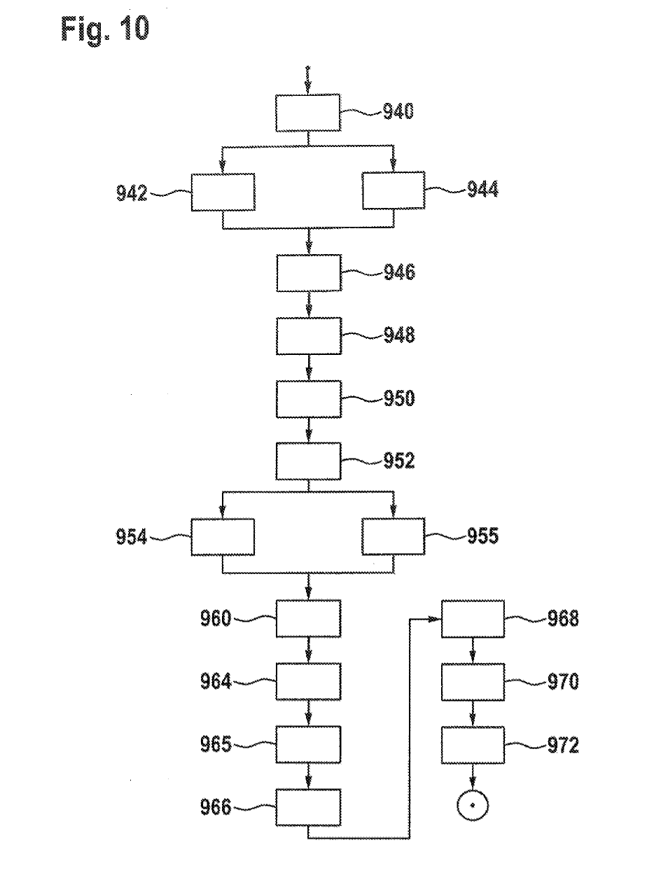

FIG. 10 shows a flow diagram of a method, according to a further embodiment of the disclosure, which serves for producing a thermoelectric module, in which a plurality of thermoelectric leg elements are electrically connected in series at opposite ends by way of conductor tracks. In step 940, an upper and a lower electrically conducting plate of a solid sheet-metal material are provided. In step 942, in both electrically conductive plates zones of weakness, in which the thickness of the respective plate is reduced, are formed by pressing in the bordering region of the conductor tracks between conductor track regions that are intended as conductor tracks to connect the leg elements to one another in the finished module. In alternative embodiments, the zones of weakness may also be formed for example by perforating. At the same time as step 942, slots that increase the mechanical stability in the region of the conductor tracks themselves by waviness are stamped in as step 944.

In step 946, the electrically conducting plates are coated with a paste containing silver powder, the coating being performed in particular at locations at which columnar leg elements of a thermoelectric material of the type of conduction n and of the type of conduction p are later to be positioned. In alternative embodiments, the paste may be applied to the leg elements at both base areas of the columnar form. Subsequently, the lower electrically conducting plate, which is intended for the later cold side of the module, is placed into a clamping device. In step 948, two comb-like auxiliary tools are arranged over the lower electrically conducting plate in such a way that rectangular regions of a uniform size that remain free and correspond in cross section to the columnar leg elements form between the prongs of the auxiliary tools, in the projection onto the plane of the lower electrically conducting plate. In step 950, the leg elements, which have an identical height exceeding the auxiliary tools, are inserted in an alternating manner into the regions remaining free, so that a checkerboard-like pattern of leg elements of the types of conduction n and p is obtained. At two corners, at which no silver paste has been applied to the electrically conducting plate in step 946, no leg elements are in this case set.

In step 952, the upper electrically conducting plate is placed onto the upper ends of the leg elements, and the arrangement thus produced, comprising the lower electrically conducting plate, the leg elements and the upper electrically conducting plate, is braced in the clamping device. In a subsequent heat treatment of the arrangement, in step 954, the lower ends of the leg elements are connected in a material-bonded manner to the lower electrically conducting plate, while at the same time, in step 955, the upper ends of the leg elements are connected in a material-bonded manner to the upper electrically conducting plate, since sintering of the silver powder located in the regions between the ends of the leg elements and the adjoining respective electrically conducting plate occurs.

In step 960, the material-bonded assembly produced by the heat treatment in steps 954 and 955, comprising the lower electrically conducting plate, the leg elements and the upper electrically conducting plate, is released from the clamping device, the comb-like auxiliary tools are pulled out from the assembly to the sides, and an aluminum-oxide powder is filled into the free space between the leg elements.

In step 964, the bonded assembly is placed into an electron-beam cutting device and the lower electrically conducting plate is cut up by means of an electron beam along the zones of weakness formed in step 942 into a first multiplicity of conductor tracks, by which every two adjacent leg elements of different types of conduction are electrically and mechanically connected to one another. Subsequently, in step 965, the bonded assembly is turned and the upper electrically conducting plate is cut up by means of the electron beam along the zones of weakness formed in step 942 into a second multiplicity of conductor tracks, by which every two adjacent leg elements of different types of conduction are electrically and mechanically connected to one another, so that altogether an electrical series connection of the leg elements is obtained.

In step 966, depending on the design of the module, superfluous regions of the upper and/or lower electrically conducting plate that possibly remain between the conductor track regions are removed. In alternative embodiments, this step may be omitted. In step 968, the aluminum-oxide powder is removed from the bonded assembly by means of a blower.

In step 970, for external connection, terminal conductor tracks are attached by hard soldering at the corner positions that have not been loaded with legs in step 950. In step 970, the thermoelectric module thus produced is enclosed between two heat-conducting, electrically insulating outer plates.

What is claimed is:

1. A method for producing a thermoelectric module with a plurality of thermoelectric leg elements, which have respectively opposite ends and are electrically connected in series, comprising:
arranging the leg elements on an electrically conducting plate;
connecting the leg elements to the electrically conducting plate; and
cutting the electrically conducting plate into a plurality of conductor tracks, each of which respectively connects two leg elements of the plurality of leg elements to one another.

2. The method according to claim 1, further comprising:
forming a zone of weakness by mechanically or chemically pretreating a bordering region between a region of a conductor track of the plurality of conductor tracks and a remaining region of the electrically conducting plate before the arranging of the leg elements, the arranging of the leg elements being performed on both sides of the zone of weakness.

3. The method according to claim 1, further comprising:
forming a slot in a region of at least one conductor track of the plurality of conductor tracks before the cutting of the electrically conducting plate.

4. The method according to claim 1, wherein the arranging of the leg elements is performed in rows, and the method further comprises:
inserting at least one row spacer into at least one row interspace between adjacent rows.

5. The method according to claim 4, the inserting of the at least one row spacer being performed before the arranging of the leg elements

6. The method according to claim 1, wherein the connecting of the leg elements to the electrically conducting plate includes forming a material-bonded connection between the leg elements and the electrically conducting plate.

7. The method according to claim 6, further comprising:
applying a connecting material for the material-bonded connection to at least one of the electrically conducting plate and the ends of the leg elements.

8. The method according to claim 7, wherein the material-bonded connection is formed by a heat treatment for at least one of melting and sintering the connecting material.

9. The method according to claim 1, wherein the cutting of the electrically conducting plate is performed by one of a laser beam, an electron beam, a high- pressure water jet, and a cut-off wheel.

10. The method according to claim 1, further comprising:
arranging a further electrically conducting plate on the leg elements, opposite from the electrically conducting plate;
connecting the leg elements to the further electrically conducting plate; and
cutting the further electrically conducting plate into a further plurality of conductor tracks, each of which respectively connects two leg elements of the plurality of leg elements to one another, after the connecting of the leg elements to the electrically conducting plate and the connecting of the leg elements to the further electrically conducting plate.

11. The method according to claim 10, further comprising:
filling a powdered substance in between the electrically conducting plate and the further electrically conducting plate, before at least one of the cutting of the electrically conducting plate and the cutting of the further electrically conducting plate.

12. A pre-product for production of a thermoelectric module with a plurality of thermoelectric leg elements, each of which has respectively opposite ends and are electrically connected in series by way of conductor tracks, comprising:
an electrically conducting plate with a plurality of conductor track regions configured for the formation of conductor tracks,
wherein the electrically conducting plate has a lower mechanical stability in at least one zone of weakness between two conductor track regions than in the conductor track regions.

13. The pre-product according to claim 12, wherein the zone of weakness has at least one of at least one clearance in the electrically conducting plate and a smaller thickness of the electrically conducting plate in relation to the conductor track regions.

14. The pre-product according to claim 12, wherein at least one conductor track region of the plurality of conductor track regions includes at least one slot formed within the at least one conductor track region.

15. The pre-product according to claim 14, wherein at least one conductor track region of the plurality of conductor track regions has a meandering contour.

16. The method according to claim 5, wherein the at least one row spacer is inserted into the lower part of a clamping device.
